(19) United States
(12) Patent Application Publication
(10) Pub. No.: US 2010/0006429 A1
(43) Pub. Date: Jan. 14, 2010

(54) SPUTTERING APPARATUS AND MANUFACTURING APPARATUS FOR LIQUID CRYSTAL DEVICE

(75) Inventors: Shinichi Fukada, Hachioji (JP); Hideo Nakata, Chino (JP); Takao Tanaka, Suwa (JP); Motohiro Kamijima, Chitose (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 12/500,010

(22) Filed: Jul. 9, 2009

(30) Foreign Application Priority Data
Jul. 10, 2008 (JP) 2008-180394

(51) Int. Cl. C23C 14/34

(52) U.S. Cl. 204/298.11

(57) ABSTRACT

A sputtering apparatus includes: a film forming chamber that houses a substrate hold so as to be capable of being carried in a horizontal direction; a sputtered particle ejecting section that includes an upper target and a lower target that are disposed so as to face each other and oblique to the substrate, and an opening, and in which sputtered particles are generated from a pair of the targets by plasma, and the sputtered particles are ejected from the opening to the substrate carried from a side adjacent to the upper target to another side adjacent to the lower target; and a slit member that has a slit through which the sputtered particles are selectively passed, and is disposed between the substrate and the sputtered particle ejecting section. The slit member is disposed so that a slit open end of the slit is positioned within 50 mm from an upstream open end of the opening of the sputtered particle ejecting section, and the slit open end is positioned at an upstream side in a carrying direction of the substrate.

The entire disclosure of Japanese Patent Application No. 2008-180394, filed Jul. 10, 2008 is expressly incorporated by reference herein.

### BACKGROUND

1. Technical Field

The present invention relates to a sputtering apparatus and a manufacturing apparatus for a liquid crystal device.

2. Related Art

A liquid crystal device used as light modulation means for projection type display such as a liquid crystal projector includes a pair of substrates, a sealant provided between the substrates at their marginal areas, and a liquid crystal layer sealed between the substrates. The inner surfaces of the pair of the substrates have electrodes that apply a voltage to the liquid crystal layer. At the inner sides of the electrodes, orientation films are formed that control the orientation of liquid crystal molecules when a non-selective voltage is applied. The liquid crystal device structured as above modulates light from a light source based on the orientation change of the liquid crystal molecules when a non-selective voltage is applied and when a selective voltage is applied, so as to form a display image.

As for the orientation film, one is generally used that is a film of polymer such as polyimide having a side-chain alkyl group and the surface of which film has been subjected to rubbing. While such rubbing is convenient, various problems arise because the method gives orientation property to the polyimide film by physically rubbing it. Specifically, the following problems are pointed out. (1) It is difficult to maintain uniform orientation. (2) Traces caused by rubbing likely remain. (3) It is not possible to control an orientation direction as well as selectively control a pretilt angle. (4) The method is not suitable for being applied to a liquid crystal panel using a multi domain method for achieving a wide view angle. (5) The method causes static electricity generated from a glass substrate to destroy thin film transistor elements or to damage orientation films, resulting in the yield being lowered. (6) Display failures likely occur that are caused by foreign materials generated from a rubbing cloth.

In addition, when such orientation film made from an organic material is used for an apparatus equipped with a high-output light source such as a liquid crystal projector, the organic material is damaged by light energy, causing orientation failures. Particularly, for downsized and high-brightness projectors, the damages are accelerated. In the projectors, energy per unit area incident on the liquid crystal panel increases. Polyimide decomposes itself due to the absorption of incident light, and heat generated by the light absorption further accelerates the decomposition. As a result, the orientation film is heavily damaged, lowering display characteristics of the apparatus.

In order to solve such problems, a method has been proposed in which a sputtering is conducted so that sputtered particles ejected from targets oppositely disposed are obliquely incident on a substrate from one direction, and an inorganic orientation film is formed on the substrate, which film has a plurality of columnar structure of crystals grown in a direction oblique to the substrate. For example, refer to JP-A-2007-286401.

In this regard, a method capable of forming an inorganic orientation film having higher reliability is expected in a sputter apparatus of a facing target type disclosed in JP-A-2007-286401. In order to improve the reliability of the inorganic orientation film, it is important to enhance the controllability of the incident angle of the sputtered particles with respect to the substrate.

### SUMMARY

An advantage of the invention is to provide a sputtering apparatus of a facing target type that can form a film having high reliability, and a manufacturing apparatus of a liquid crystal device.

According to a first aspect of the invention, a sputtering apparatus includes: a film forming chamber that houses a substrate hold so as to be capable of being carried in a horizontal direction; a sputtered particle ejecting section that includes an upper target and a lower target that are disposed so as to face each other and oblique to the substrate, and an opening, and in which sputtered particles are generated from a pair of the targets by plasma, and the sputtered particles are ejected from the opening to the substrate carried from a side adjacent to the upper target to another side adjacent to the lower target; and a slit member that has a slit through which the sputtered particles are selectively passed, and is disposed between the substrate and the sputtered particle ejecting section. The slit member is disposed so that a slit open end of the slit is positioned within 50 mm from an upstream open end of the opening of the sputtered particle ejecting section, and the slit open end is positioned at an upstream side in a carrying direction of the substrate.

The sputtering apparatus can form on the substrate a sputter film in which an orientation direction is controlled at a desired angle since the sputtered particles contributing to forming the film are selected by the slit. In this case, the sputtered particles in a relatively high sputter rate region are ejected to the substrate since the slit open end is positioned within 50 mm from the upstream open end of the opening. As a result, good film quality can be achieved. The slit member can prevent the substrate from being influenced by, for example, plasma leaked out from the sputtered particle ejecting section. That is, the following problem can be prevented. The wettability of the substrate is enhanced if the substrate is exposed with plasma. Thus, it becomes difficult to control the deposition conditions of the sputtered particles since the sputtered particles easily adhere on the substrate. As a result, a sputter film having high reliability can be manufactured.

In the sputtering apparatus, a distance between the slit member and the substrate is preferably 1 mm or more and 10 mm or less.

Since the distance between the slit member and substrate is 1 mm or more, a problem can be prevented in that the slit member and the substrate interfere with each other because they approach each other more than necessary. It can also be prevented that the substrate is contaminated because the substrate approaches too closely to the sputter source. In addition, the distance between the slit member and the substrate is less than the mean free path of the sputtered particles since the distance between the slit member and the substrate is 10 mm or less. Accordingly, the sputtered particles passing through the slit can be deposited on the substrate, resulting in a problem being suppressed in that the sputtered particles sneak around the back side of the substrate.

In the sputtering apparatus, another slit open end positioned in a downstream side in the carrying direction of the substrate is preferably positioned by a distance in a range of from 10 mm or more to 300 mm or less from the upstream open end.

This structure allows forming a sputter film on the substrate by using sputtered particles in a particularly high sputter rate region.

In the sputtering apparatus, the sputtered particle ejecting section preferably holds each of the pair of the targets oblique to a normal line of the substrate by 10 degrees to 60 degrees.

The pair of the targets obliquely disposed within such range with respect to the substrate allows controlling the orientation condition of sputter film formed on the substrate with high accuracy and forming on the substrate a sputter film having a desired orientation condition.

The sputtering apparatus preferably further includes a substrate transfer unit capable of carrying the substrate at a constant velocity in the film forming chamber.

This structure allows forming a sputter film having a uniform thickness on the substrate along the carrying direction since the substrate is carried by the constant velocity.

According to a second aspect of the invention, a manufacturing apparatus of a liquid crystal device that includes a liquid crystal layer sandwiched between a pair of substrates, and an inorganic orientation film formed at an inner side of at least one of the substrates, includes the sputtering apparatus of the first aspect. The inorganic orientation film is formed by the sputtering apparatus.

The manufacturing apparatus can manufacture a liquid crystal device having an inorganic orientation film superior in orientation property with a desired columnar structure since the device includes the sputtering apparatus capable of well controlling the ejecting direction of the sputtered particles.

### BRIEF DESCRIPTION OF THE DRAWINGS

The invention will be described with reference to the accompanying drawings, wherein like numbers reference like elements.

FIGS. 1A and 1B are schematic views showing a rough structure of a sputter apparatus.

FIGS. 2A and 2B are views showing a detailed structure of the sputter apparatus of FIGS. 1A and 1B.

FIG. 3 is a view illustrating a positional relation between a slit plate and a sputtered particle ejecting section.

### DESCRIPTION OF EXEMPLARY EMBODIMENTS

Embodiments of the invention are described below with reference to accompanying drawings. The technical scope of the invention is not limited to the following embodiments. Note that scales of members in the drawings referred to hereinafter are adequately changed so that they can be recognized. In the following drawings, a carrying direction of a substrate in a film forming chamber is defined as an X direction. A thickness direction of the substrate is defined as a Z direction. A Y direction is orthogonal to each of the X and Z directions. A thickness direction of a target is defined as a Za direction. An ejecting direction of sputtered particles is defined as an Xa direction.

Sputtering apparatus, and manufacturing apparatus for liquid crystal device

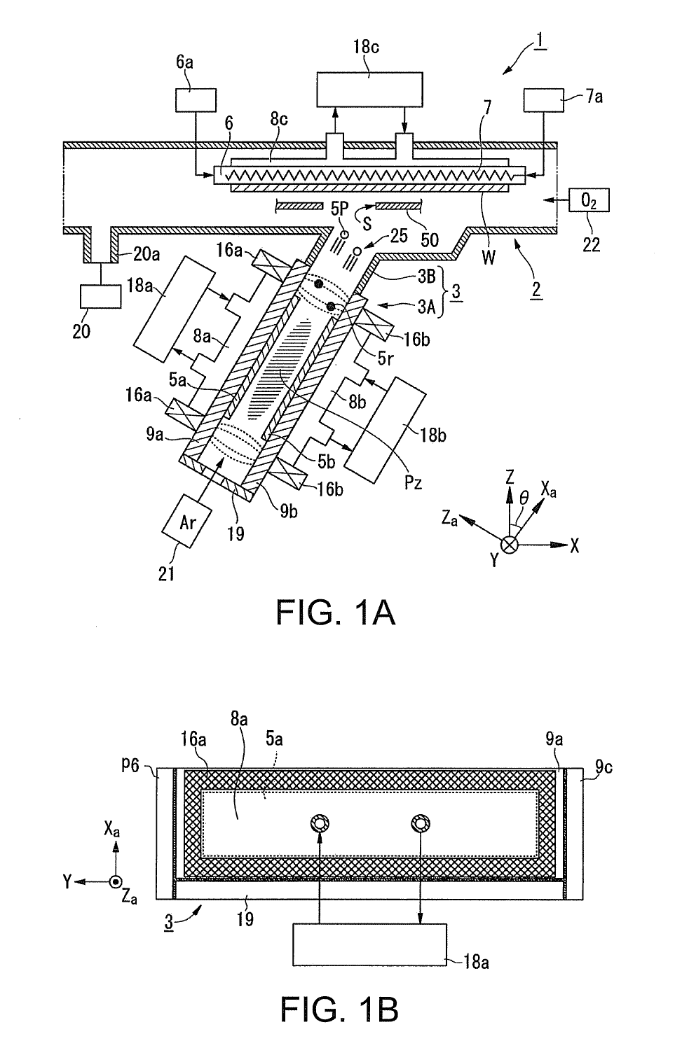

FIG. 1A is a schematic view illustrating a sputtering apparatus (hereinafter, referred to as a sputter apparatus) according to an embodiment of the invention. FIG. 1B is a side structural view of the sputter apparatus taken from a plus (+) Za direction.

A sputter apparatus 1 shown in FIG. 1A is one of manufacturing apparatuss for a liquid crystal of the invention, and forms an inorganic orientation film by sputtering on a substrate W serving as a member of a liquid crystal device. The sputter apparatus 1 includes a film forming chamber 2 that is a vacuum camber and houses the substrate W, and a sputtered particle ejecting section 3 that ejects sputtered particles to a surface of the substrate W to form an orientation film made from an inorganic material.

The sputtered particle ejecting section 3 is provided with a first gas supply unit 21 that supplies argon gas for electric discharge in a plasma generation region. The film forming chamber 2 is provided with a second gas supply unit 22 that supplies oxygen gas as reactive gas reacting with an orientation material flying over the substrate W inside the chamber to form the inorganic orientation film. The film forming chamber 2 is also coupled through a pipe 20a to an exhaust control device 20 that control the internal pressure of the chamber 2 for achieving a desired vacuum level.

The second gas supply unit 22 and the exhaust control device 20 are disposed opposite each other with respect to a connection section 3B (also, referred to as an opening section 3B). Oxygen gas supplied from the second gas supply unit 22 flows over the substrate W from a plus (+) X side to a minus (−) X side of the film forming chamber 2, i.e., to the exhaust control device 20 in a minus (−) X direction shown in FIG. 1A.

In a practical sputter apparatus, a loadlock chamber is provided outside the film forming chamber 2 in an X-axis direction. The loadlock chamber enables the substrate W to be carried in and out while the vacuum in the film forming chamber 2 is kept. The loadlock chamber is also coupled to an exhaust control device that individually controls the chamber at a vacuum atmosphere. The loadlock chamber is coupled to the film forming chamber 2 with a gate valve that air-tightly closes therebetween. As a result, the substrate W can be carried in and out while the film forming chamber 2 is not opened to the atmosphere.

The sputter apparatus 1 has a substrate holder 6 that holds a surface on which a film is formed (a film-formed surface) of the substrate W horizontally, i.e., in parallel with an X-Y plane. The substrate holder 6 is coupled to a transfer unit 6a horizontally carrying the substrate holder 6 from a side adjacent to the loadlock chamber (not shown) to another side opposite to the side. A carrying direction of the substrate W by the transfer unit 6a is in parallel with the X-axis direction in FIG. 1A, and is orthogonal to the lengthwise directions (a Y-axis direction) of a first target 5a and a second target 5b. The transfer unit 6a can carry the substrate W at a constant velocity. Thus, an inorganic orientation film can be formed on the substrate W with a good quality by sputtered particles 5P ejected from the sputtered particle ejecting section 3. The details are described latter.

The sputtered particle ejecting section 3 includes the first target 5a and the second target 5b both of which are disposed so as to face each other. That is, the sputtered particle ejecting section 3 constitutes a so-called facing target type sputter apparatus. The sputtered particle ejecting section 3 also includes a box-shaped chassis 3A, and the connection section 3B for attaching the box-shaped chassis 3A to the film forming chamber 2. The connection section 3B is composed of a flange and the like for coupling the box-shaped chassis 3A to the film forming chamber 2.

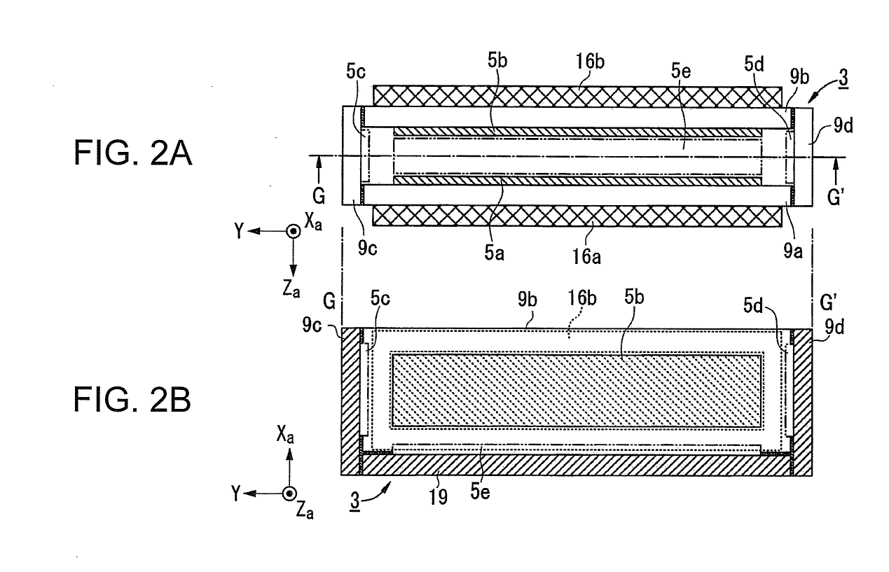

FIGS. 2A and 2B show a structure of the sputtered particle ejecting section 3 shown in FIG. 1A. FIG. 2A is a plan view showing the sputtered particle ejecting section 3 viewed from the film forming chamber 2. FIG. 2B is a sectional view taken along a line G-G′ of FIG. 2A.

As shown in FIGS. 1A, 1B, 2A, and 2B, the box-shaped chassis 3A, which serves as a vacuum chamber of the sputtered particle ejecting section 3, is composed of a first electrode 9a, a second electrode 9b, and sidewall members 19, 9c and 9d. One ends (at a side in a minus (−) Xa direction) of the first electrode 9a and the second electrode 9b are connected to the sidewall member 19. In the Y-axis direction, one ends of the first electrode 9a and the second electrode 9b are connected to the sidewall member 9c while the other ends of them are connected to the sidewall 9d. In this regard, the first electrode 9a, the second electrode 9b, and the sidewall members 9c, 9d, and 19, are insulated from each other. One end of the connection section 3B communicates with the box-shaped chassis 3A while the other end thereof communicates with the inside the film forming chamber 2. That is, the opening section 3B is interposed between the box-shaped chassis 3A and the film forming chamber 2. This structure enables the box-shaped chassis 3A to eject the sputtered particles 5P into the film forming chamber 2 from ends, opposite to the sidewall member 19, of the first electrode 9a and the second electrode 9b through the opening section 3B.

The first target 5a is attached to the first electrode 9a having an approximately flat-plate shape while the second target 5b is attached to the second electrode 9b having an approximately flat-plate shape. The first and second target 5a and 5b are made of a material, such as silicon, containing a constituting substance of the inorganic orientation film formed on the substrate W, and supported by the electrodes 9a and 9b. As the shape of the first and second targets 5a and 5b, an elongate plate shape extending in the Y direction is employed (refer to FIGS. 2A and 2B). The first and second targets 5a and 5b are disposed so that the opposed faces are approximately parallel.

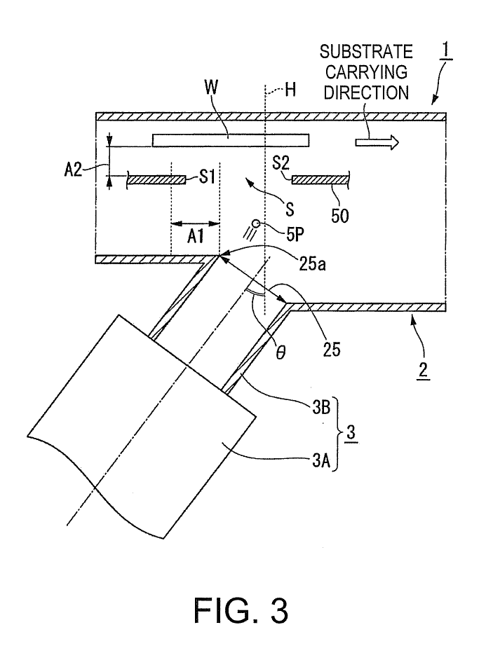

The connection section 3B is formed so that a face direction of the targets 5a and 5b held inside the sputtered particle ejecting section 3 makes a desired angle θ with respect to a normal direction (a dashed line H in FIG. 3) of the film-formed surface of the substrate W housed inside the film forming chamber 2. The connection section 3B allows the box-shaped section 3A connected to one end thereof to be obliquely disposed at a desired angle with respect to the substrate W.

That is, with the connection section 3B, the first and second targets 5a and 5b attached to the electrodes 9a and 9b are slanted with respect to the substrate W. The first target 5a (upper target) is disposed at a substrate W side (in a plus (+) Z direction) while the second target 5b (lower target) is disposed at a lower side (in a minus (−) Z direction) with respect to the first target 5a.

As described above, in the embodiment, the sputtered particle ejecting section 3 ejects the sputtered particles 5P to the substrate W carried inside the film forming chamber 2 by the transfer device 6a from a side adjacent to the first target 5a to another side adjacent to the second target 5b (i.e., +X direction). As a result, the inorganic orientation film is formed on the substrate W.

More specifically, as for the desired angle θ, the targets 5a and 5b are preferably held so as to be slanted at an angle of 10 to 60 degrees with respect to the normal line direction of the substrate W. Setting the slanted angle of the targets 5a and 5b with respect to the substrate W within the above range allows forming a desired inorganic orientation film.

The first electrode 9a is coupled to a power source(not shown) of a direct current power source or a high frequency power source while the second electrode 9b is coupled to a power source(not shown) of a direct current power source or a high frequency power source. Electric power supplied from the power sources to the targets 5a and 5b generates plasma Pz in a space (a plasma generation region) between the targets 5a and 5b.

A first cooling unit 8a for cooling the target 5a is disposed on one face of the first electrode 9a while the target 5a is attached on the other face opposite to the one face. The first cooling unit 8a is coupled to a first coolant circulation unit 18a with pipes and the like. Likewise, a second cooling unit 8b for cooling the target 5b is disposed on one face of the second electrode 9b while the target 5b is attached on the other face opposite to the one face. The second cooling unit 8b is coupled to a second coolant circulation unit 18b with pipes and the like. As shown in FIG. 1B, the first cooling unit 8a is sized in approximately same planar dimensions of the target 5a, and is disposed at a position overlapping with the target 5a in plan view with the first electrode 9a interposed therebetween. Likewise, the second cooling unit 8b (not shown in FIG. 1B) is disposed at a position overlapping with the target 5b in plan view. The cooling units 8a and 8b include coolant flow passages for circulating the coolant inside thereof. The coolant supplied from the coolant circulation units 18a and 18b is circulated in the coolant flow passages to cool the targets 5a and 5b.

As shown in FIG. 1A, the first gas supply unit 21 is coupled to the sidewall member 19 disposed so as to face the film forming chamber 2 with the plasma generation region between the targets 5a and 5b interposed therebetween. Argon gas supplied from the first gas supply unit 21 flows in the plasma generation region (a target-facing region) through the sidewall member 19, and then flows in the film forming chamber 2 trough the connection section 3B. The argon gas flowed in the film forming chamber 2 and oxygen gas that is supplied from the second gas supply unit 22 and flows are joined together to flow to the exhaust control device 20.

As shown in FIG. 1B, a first magnetic field generation unit 16a is disposed so as to surround the first cooling unit 8a having a rectangular shape in plan view. The first magnetic field generation unit 16a is composed of magnets such as permanent magnets having a rectangular shape, electromagnets, and magnets of a combination thereof. Likewise, a second magnetic field generation unit 16b surrounding the second cooling unit 8b shown in FIG. 1A has a similar shape of the first magnetic field generation unit 16a.

Here, the cooling units 8a and 8b may be made of a conductive material, and be electrically coupled to the electrodes 9a and 9b, respectively. In this case, the power sources can be electrically coupled to the cooling units 8a and 8b, respectively. The electrodes 9a and 9b may serve as the cooling units as well as the electrodes by forming the coolant flow passages inside thereof.

As shown in FIGS. 1A, 1B, 2A, and 2B, the first magnetic field generation unit 16a and the second magnetic field generation unit 16b are disposed so as to face each other in outer peripheral areas of the targets 5a and 5b disposed so as to face each other. The magnetic field generation units 16a and 16b generate a magnetic field in the Za direction inside the sputtered particle ejecting section 3 so as to surround the targets 5a and 5b. The magnetic field traps electrons in the plasma Pz in the plasma generation region. That is, the magnetic field generation units 16a and 16b form an electron-trap unit.

The substrate holder 6 is provided with a heater (heating unit) 7 for heating the substrate W held by the holder 6. In addition, the substrate holder 6 is provided with a third cooling unit 8c for cooling the substrate W held by the holder 6. The heater 7 is coupled to a controller 7a having a power source and the like. The heater 7 is adapted to heat the substrate holder 6 at a desired temperature by a heating up operation controlled by the controller 7a, resulting in the substrate W being heated at the desired temperature. On the other hand, the third cooling unit 8c is coupled to a third coolant circulation unit 18c with pipes. The third cooling unit 8c is adapted to cool the substrate holder 6 at a desired temperature by circulating coolant supplied from the third coolant supply unit 18c, resulting in the substrate W being cooled at the desired temperature.

In order to improve quality of the inorganic orientation film formed on the substrate W, the sputter apparatus 1 of the embodiment includes a slit plate (slit member) 50 having a slit S inside the film forming chamber 2. The slit plate 50 is disposed between the sputtered particle ejecting section 3 and the substrate W. The slit S selectively passes the sputtered particles 5P ejected to the substrate W from the sputtered particle ejecting section 3. The slit plate 50 is made of nonmagnetic metal such as aluminum, and is electrically conducted to a sidewall of the film forming chamber 2 in a region not shown so as to be kept at a grounded potential. The slit plate 50 is disposed so as to satisfy a predetermined relation with the sputtered particle ejecting section 3, which is described later in detail.

FIG. 3 is a view illustrating a positional relation between the slit plate 50 and the sputtered particle ejecting section 3. The slit plate 50 selectively passes the sputtered particles 5P in an opening region formed by the slit S, enabling a film condition (film quality) formed with the sputtered particles 5P to be controlled.

Here, in the sputtered particle ejecting section 3, a sputter rate (a film forming velocity) tends to gradually lowered as the distance from an open end of an opening 25 increases. Therefore, a positional relation between the opening 25 of the sputtered particle ejecting section 3 and the slit S of the slit plate 50 is important.

The slit plate 50 of the embodiment is disposed so that a slit open end S1 is positioned in a region shown as A1 in FIG. 3. More specifically, the slit open end S1 is positioned within 50 mm from an upstream side open end 25a of the opening 25 to an upstream side (−X direction) in the carrying direction of the substrate W. In forming a film, a region needs to be selected in which the film forming velocity is achieved as high as possible, from both points of views of film-quality controllability and process throughput. From these points of views, in the region A1 within 50 mm from the upstream side open end 25a, an inorganic orientation film can be formed on the substrate W carried from the upstream side with a good quality from the initial stage of forming a film. Because, the film forming velocity is relatively high in the region A1 even if the targets are slanted except for a case in which the targets are extremely slanted, e.g., slanted to almost a horizontal position such as θ>80 degrees. In contrast, in a region at the upstream side (−X direction) from the region A1, it is difficult to form an inorganic orientation film on the substrate W with a good quality because the film forming velocity is low.

On the other hand, it is enough that a slit open end S2 at a downstream side in the carrying direction of the substrate W is positioned in such a manner that the slit open region is positioned in a region in which the film forming velocity is high. The slit open end S2 may be positioned in the downstream side from the upstream open end 25a of the opening 25 of the sputtered particle ejecting section 3. More specifically, the slit open end S2 is preferably positioned in a region of 10 mm or more to 300 mm or less from the upstream open end 25a at which a sputter rate is high. Widening the slit open section without reason may increase the risk of not only forming a poor film on the uppermost surface but also being influenced by plasma leaked out in any way. The slit open region is preferably set 300 mm or less. As a result, the inorganic orientation film can be formed on the substrate W by using a region in which the sputter rate is high.

In addition, in order to form an inorganic orientation film with a good quality, the distance between the slit plate 50 and the substrate W is also very important factor. If the distance between the slit plate 50 and the substrate W is set less than 1 mm, the substrate W and the slit plate 50 may interfere with each other since they approach each other more than necessary. In contrast, if the distance between the slit plate 50 and the substrate W is set more than 10 mm, a problem may arise in that the sputtered particles 5P sneak around the back side of the substrate W since the distance between the slit plate 50 and the substrate W becomes larger than a mean free path.

In order to prevent such problem, in the embodiment, a distance A2 is set from 1 mm or more to 10 mm or less. The distance A2 is the distance between the slit plate 50 and the substrate W, i.e., the distance between the slit plate 50 and the film-formed surface of the substrate W. This distance enables the sputtered particles 5P passing through the slit S to well adhere on the substrate W. As a result, forming a sputter film can be conducted with high reliability.

An inorganic orientation film is formed on the substrate W, which is a constituting member of a liquid crystal device, by the sputter apparatus 1 in the following manner. While argon gas is introduced from the first gas supply unit 21, a DC power (RF power) is supplied to the first electrode 9a and the second electrode 9b so as to generate the plasma Pz in the space between the targets 5a and 5b. Argon ions and the like in a plasma atmosphere collide against the targets 5a and 5b so as to sputter an orientation film material (silicon) from the targets 5a and 5b as the sputtered particles 5P. Out of the sputtered particles 5P in the plasma Pz, only the sputtered particles 5P flying from the plasma Pz to the opening 25 are ejected to the film forming chamber 2.

The sputtered particles 5P flying over the surface of the substrate W from an oblique direction react with oxygen gas flowing in the film forming chamber 2 on the substrate W to form an orientation film made of a silicon oxide.

In the embodiment, a case is described in which silicon as the sputtered particles 5P reacts with oxygen gas as the second sputter gas to form a silicon oxide on the substrate W. Alternatively, the targets 5a and 5b are made of, for example, a silicon oxide (SiOx) or an aluminum oxide (AlOy). With RF power being supplied, the targets 5a and 5b are sputtered, enabling an inorganic orientation film made of the silicon oxide or the aluminum oxide to be formed on the substrate W. In this case, the second sputter gas (oxygen gas) continuing to flow in the film forming chamber 2 can prevent an oxide composition of the formed inorganic orientation film from shifting from a desired composition. As a result, insulation property of the inorganic orientation film can be improved.

In the sputter apparatus 1 structured as described above, the sputtered particle ejecting section 3 of a facing target type is obliquely disposed by a predetermined angle (θ: 10 to 60 degrees) with respect to the substrate W. As a result, the sputtered particles 5P ejected from the opening 25 of the sputtered particle ejecting section 3 can be incident on the film-formed surface of the substrate W at a predetermined angle.

In the embodiment, the sputtered particles 5P having a high sputter rate that pass through the slit S formed in the slit plate 50 disposed between the opening 25 and the substrate W, are deposited, enabling an inorganic orientation film having a columnar structure oriented in one direction to be formed on the substrate W.

The sputtered particle ejecting section 3 of a facing target type can achieve extremely high target use efficiency because sputtered particles not ejected from the opening 25 are mainly incident on the targets 5a and 5b to be reused. Additionally, in the sputtered particle ejecting section 3, narrowing the target distance can enhance directivity of sputtered particles ejected from the opening 25, highly controlling the incident angle of sputtered particles that reach the substrate W. As a result, the orientation property of the columnar structure in the formed inorganic orientation film can be enhanced.

The sputter apparatus 1 of the embodiment can trap or reflect electrons 5r in the plasma Pz, in forming the film, by magnetic field generated by the magnetic field generation units 16a and 16b that surround the targets 5a and 5b of the sputtered particle ejecting section 3 and have a rectangular-frame shape (refer to FIGS. 1A and 1B), enabling the plasma Pz to be well trapped in the region between the targets 5a and 5b. As a result, increasing the wettability of the substrate W due to the electrons 5r incident on the surface of the substrate W can be prevented.

There may be a case in which the electrons and the like leak out from the magnetic field generation units 16a and 16b, though they are provided to serve as an electron trapping unit, and reach the substrate W, resulting in the wettability of the surface of the substrate W to increase. This increase may cause migration of sputtered particles to occur, hindering the formation of the columnar structure. In this regard, in the embodiment, the slit plate 50 is kept at the grounded potential as described above, so that electrons or ionized substances in the plasma Pz that leak out from the sputtered particle ejecting section 3 can be trapped by the slit plate 50 to be removed. This structure can prevent the substrate W from being influenced by the plasma Pz. As a result, an inorganic orientation film having high reliability can be formed on the substrate W.

Consequently, the sputter apparatus 1 of the embodiment can readily form the inorganic orientation film having high orientation property on the substrate W.

The sputter apparatus 1 includes the targets 5a and 5b each having an elongate-plate shape so that sputtered particles can be ejected from the sputtered particle ejecting section 3 in a line-like form extending in the Y-axis direction. In addition, the substrate holder 6 can carry the substrate W in a direction (the X-axis direction) perpendicular to the line-like shape formed by the sputtered particles. The substrate W can be scanned by the line-like-shape formed by the sputtered particles so as to form a film in a planar shape as a continuous substrate process, resulting in high productive efficiency being achieved.

The substrate holder 6 is provided with the third cooling unit 8c for cooling the substrate W. The third cooling unit 8c cools the substrate W in forming a film so as to maintain the substrate W at a predetermined temperature such as a room temperature and suppress orientation material molecules deposited on the substrate W by sputtering from diffusing (migrating) on the substrate W. This results in a local growth of the orientation material being enhanced on the substrate W, enabling an orientation film grown in one axis direction in a columnar shape to be readily obtained.

The sputter apparatus 1 is not limited to the structure of the embodiment and various changes can be made without departing from the spirit of the invention.

For example, the sputter apparatus of a counter type sputter apparatus can include targets 5c, 5d, and 5e provided to the sidewall members 9c, 9d, and 19 respectively while the targets 5a and 5b are respectively supported by the first electrode 9a and second electrode 9b, both of which are two opposed sidewalls of the box-shaped chassis in the embodiment. In such structure, when a power source is coupled to each of the sidewall members 9c, 9d, and 19 so as to supply power to each of the targets 5c, 5d, and 5e, sputtered particles ejected from the targets 5c, 5d, and 5e can be used for forming a film. As a result, it can be expected to enhance the film forming velocity. In addition, since the targets 5a to 5e are disposed so as to surround the plasma generation region, sputtered particles excluding ones ejected to the film forming chamber 2 from the opening 25 are incident on the targets 5a to 5e surrounding the plasma Pz to be reused for generating other sputtered particles. As a result, target use efficiency can be enhanced.

In the structure, cooling units are preferably provided juxtaposed to the respective sidewall members 9c, 9d, and 19 for cooling the targets 5c, 5d, and 5e. More preferably, the arrangement of the electron trapping units (magnetic field generation units) corresponding to the targets 5c, 5d, and 5e additionally provided are changed to optimize the positional relation between the plasma Pz and the targets 5a to 5e.

Method for Manufacturing Liquid Crystal Device

A method for manufacturing a liquid crystal device (steps for forming an inorganic orientation film on the substrate W) is described that uses a apparatus including the sputter apparatus 1 for manufacturing a liquid crystal device (hereinafter, referred to as a manufacturing apparatus).

First, as the substrate W, a substrate serving as a substrate for a liquid crystal device is prepared on which predetermined constitutional members such as switching elements and electrodes are formed. Next, the substrate W is housed inside the loadlock chamber juxtaposed to the film forming chamber 2, and thereafter, the inside of the loadlock chamber is depressurized so as to be a vacuum state. Independently from the step, the inside of the film forming chamber 2 is controlled at a desired vacuum level by operating the exhaust control device.

Subsequently, the substrate W is carried inside the film forming chamber 2 to be set to the substrate holder 6. Then, the substrate W is heated by the heater 7 of the substrate holder 6, for example, at about 250° C. to about 300° C. to remove moisture and gas adsorbed on the surface of the substrate W as a pretreatment for forming an orientation film. After the heating by the heater 7 is stopped, in order to suppress increasing the substrate temperature due to sputtering, coolant is circulated in the third cooling unit 8c by operating the third coolant circulation unit 18c so as to maintain the substrate W at a predetermined temperature such as a room temperature.

Next, argon gas is introduced inside the sputtered particle ejecting chamber 3 from the first gas supply unit 21 at a predetermined flow rate while oxygen gas is introduced inside the film forming chamber 2 from the second gas supply unit 22 at a predetermined flow rate. Meantime, the inside of the film forming chamber 2 is controlled at a predetermined operational pressure, for example, about 10⁻¹ Pa by operating the exhaust control device 20. In the manufacturing apparatus of the embodiment, only argon gas is introduced in the plasma generation region, i.e., in front of the targets 5a and 5b while oxygen gas is flowed over the substrate W from the gas supply path of different supply system, because oxygen radicals and negative oxygen ions are generated in the oxygen gas plasma. In forming a film, the substrate W is preferably maintained at a room temperature by operating the heater 7 and the third cooling unit 8c as needed.

Under such film forming conditions, a sputtering is conducted in the sputtered particle ejecting section 3 while the substrate W is moved by the transfer unit (substrate transfer unit) 6a in the X direction in FIG. 1A at a predetermined velocity. In the sputtered particle ejecting section 3 of a facing target type, sputtered particles (silicon) serving as an orientation film material are ejected from the targets 5a and 5b. The sputtered particles moving in the direction between the targets are trapped in the plasma Pz while only the sputtered particles moving in the target face direction are ejected from the opening 25 into the film forming chamber 2 to be incident on the substrate W.

The sputtered particles 5P are selectively incident on only the film-formed surface, which faces the opening of the slit S of the slit plate 50, of the substrate W so as to form a film of a silicon oxide after reacting with oxygen gas on the substrate W. As described above, the sputtered particles 5P ejected from the sputtered particle ejecting section 3 obliquely disposed with respect to the substrate W are incident on the film-formed surface of the substrate W at a predetermined angle, i.e., the angle θ. As a result, an inorganic orientation film deposited on the substrate W after reacting oxygen gas and the sputtered particles 5P has a columnar structure slanted at an angle corresponding to the incident angle θ. As aforementioned, the slit S allows the region in which the sputter rate is high to be used in forming an inorganic orientation film, enabling an inorganic orientation film to be formed on the substrate W with a good quality.

The inorganic orientation film formed on the substrate W by the manufacturing apparatus has the columnar structure having the desired angle. A liquid crystal device including the orientation film can well control the pretilt angle of liquid crystal by the inorganic orientation film.

Thereafter, the substrate W on which the inorganic orientation film has been formed is bonded to another substrate manufactured in a different steps. Liquid crystal is sealed between the substrates so that a liquid crystal device is completed. In the method for manufacturing a liquid crystal according to the invention, manufacturing steps excluding the step for forming the inorganic orientation film can employ the known manufacturing methods. As described above, the manufacturing apparatus of a liquid crystal device of the invention can form an inorganic orientation film having high orientation property and good quality by the sputter apparatus 1.

What is claimed is:

1. A sputtering apparatus, comprising:
a film forming chamber that houses a substrate hold so as to be capable of being carried in a horizontal direction;
a sputtered particle ejecting section, the section including:
an upper target and a lower target that are disposed so as to face each other and oblique to the substrate; and
an opening, wherein sputtered particles are generated from a pair of the targets by plasma, and the sputtered particles are ejected from the opening to the substrate carried from a side adjacent to the upper target to another side adjacent to the lower target; and
a slit member that has a slit and is disposed between the substrate and the sputtered particle ejecting section, the sputtered particles being selectively passed through the slit, the slit member being disposed so that a slit open end of the slit is positioned within 50 mm from an upstream open end of the opening of the sputtered particle ejecting section, the slit open end being positioned at an upstream side in a carrying direction of the substrate.

2. The sputtering apparatus according to claim 1, wherein a distance between the slit member and the substrate is 1 mm or more and 10 mm or less.

3. The sputtering apparatus according to claim 1, wherein another slit open end positioned in a downstream side in the carrying direction of the substrate is positioned by a distance in a range of from 10 mm or more to 300 mm or less from the upstream open end.

4. The sputtering apparatus according to claim 1, wherein the sputtered particle ejecting section holds each of the pair of the targets oblique to a normal line of the substrate by 10 degrees to 60 degrees.

5. The sputtering apparatus according to claim 1, further comprising a substrate transfer unit capable of carrying the substrate at a constant velocity in the film forming chamber.

6. A manufacturing apparatus of a liquid crystal device that includes a liquid crystal layer sandwiched between a pair of substrates, and an inorganic orientation film formed at an inner side of at least one of the substrates, comprising the sputtering apparatus according to claim 1, wherein the inorganic orientation film is formed by the sputtering apparatus.
